(19) United States
(12) Patent Application Publication
(10) Pub. No.: US 2018/0108872 A1
(43) Pub. Date: Apr. 19, 2018

(54) SELF-LUMINOUS DISPLAY DEVICE AND MANUFACTURING METHOD THEREOF

(71) Applicant: Shenzhen China Star Optoelectronics Technology Co., Ltd., Shenzhen City (CN)

(72) Inventor: Xianjie Li, Shenzhen City (CN)

(21) Appl. No.: 15/112,428

(22) PCT Filed: May 19, 2016
(86) PCT No.: PCT/CN2016/082584

§ 371 Date: Jul. 19, 2016

(30) Foreign Application Priority Data
May 3, 2016 (CN) 2016102869152

(51) Int. Cl. H01L 51/56; H01L 51/50; H01L 51/52; H01L 27/32; H01L 51/00

(52) U.S. Cl. CPC H01L 51/56; H01L 51/0058; H01L 51/504; H01L 51/5206; H01L 51/5088; H01L 51/5056; H01L 51/5072; H01L 51/5092; H01L 51/5221; H01L 51/524; H01L 27/3244; H01L 51/0003; H01L 51/0008; H01L 51/004; H01L 51/0037; H01L 51/0035; H01L 51/0072; H01L 51/005; H01L 51/006; H01L 2251/558; H01L 2227/323; H01L 51/502

(57) ABSTRACT

The invention provides a self-luminous display device and manufacturing thereof, which comprises a blue OLED, a green QLED and a red QLED, and the blue OLED, green QLED and red QLED sharing a common blue light emissive layer formed on all the sub-pixel areas; the green light emissive layer and the red light emissive layer disposed at corresponding green and red sub-pixel areas respectively; the blue light emissive layer formed by a vapor deposition process to overcome the problems of low emission efficiency and short life-span when manufacturing blue OLED with wet deposition; while the red and green light emissive layers formed by a wet deposition process to overcome the problems of low material utilization and high cost when manufacturing red and green QLED with vapor deposition. The present invention can reduce manufacturing cost and improve competiveness without affecting the luminous efficiency and life-span.

### BACKGROUND OF THE INVENTION

### 1. Field of the Invention

The present invention relates to the field of self-luminous display device and manufacturing method thereof.

### 2. The Related Arts

The organic light-emitting diode (OLED) display has the advantages of active light-emitting, low driving voltage, high emission efficiency, quick response time, high resolution and contrast, near 180° viewing angle, wide operation temperature range, and capability to realize flexible display and large-area full-color display, and is regarded as the most promising display technology.

In general, the structure of an OLED display, which is a self-luminous display device, comprises: a pixel electrode and a common electrode, operating respectively on an anode and a cathode, and an organic emissive functional layer sandwiched between the pixel electrode and the common electrode so that when a proper voltage is applied to the anode and the cathode, the emissive functional layer emits light. The organic emissive functional layer generally comprises a hole injection layer (HIL) disposed on the anode, a hole transport layer disposed on the HIL, am emissive layer disposed on the hole transport layer, an electron transport layer disposed on the emissive layer, and an electron injection layer (EIL) disposed on the electron transport layer. The emission principle is that, when driven by a certain voltage, the electrons and the holes migrate respectively from the EIL and HIL to the emissive layer and meet inside the emissive layer to form excitons to excite the luminescent molecules, which emit visible light through radiative relaxation.

As the technology continues to develop, higher display quality requirements are demanded from the display device. Quantum dots (QDs) are usually spherical semiconductor nano-particles made of II-VI, III-V elements, with particle diameter typically between a few nanometers to several tens of nanometers. Quantum dot material, due to the existence of the quantum confinement effect, has the originally continuous energy band transformed into discrete energy level structure, and can emit visible light with external excitation. Because of the emission peak of the quantum dot material has a smaller full width at half maximum (FWHM) and light color can be adjusted by varying the particle size, structure or composition of the quantum dot material, and therefore QD is widely in display device to effectively improve the color saturation and color gamut of the display device.

Quantum dot light-emitting diodes (QLED) and OLED are both self-luminous. The current OLED display devices are prepared mostly by using vapor deposition process, which suffers low material utilization and results in high costs, especially for large-size OLED display device. On the other hand, when using a wet deposition process for preparing OLED display device or QLED display device, almost no material waste occurs, which helps to reduce the costs of OLED display device or display device QLED. However, the blue QLED or blue OLED prepared using a wet deposition process has the problems of low luminous efficiency and short life-span.

### SUMMARY OF THE INVENTION

The object of the present invention is to provide a self-luminous display device, to reduce manufacturing cost and improve competiveness without affecting the luminous efficiency and life-span.

Another object of the present invention is to provide a manufacturing method of a self-luminous display device, to reduce manufacturing cost and improve competiveness without affecting the luminous efficiency and life-span.

To achieve the above object, the present invention provides a self-luminous display device, which comprises a substrate, a blue OLED, a green QLED and a red QLED, all disposed on the substrate, a sealant disposed on the blue OLED, green QLED and red QLED, and a cover plate disposed on the sealant to cover the substrate; the substrate being disposed with a plurality of blue sub-pixel areas, green sub-pixel areas and red sub-pixel areas arranged as an array; the blue OLED comprising: a first anode formed on the blue sub-pixel area, a blue light hole injection layer disposed on the first anode, and a blue light hole transport layer disposed on the blue light hole injection layer; the green QLED comprising: a second anode formed on the green sub-pixel area, a green light hole injection layer disposed on the second anode, a green light hole transport layer disposed on the green light hole injection layer, and a green light emissive layer disposed on the green light hole transport layer; the red QLED comprising: a third anode formed on the red sub-pixel area, a red light hole injection layer disposed on the third anode, a red light hole transport layer disposed on the red light hole injection layer, and a red light emissive layer disposed on the red light hole transport layer; the blue OLED, green QLED and red QLED further commonly comprising: a blue light common layer formed on the blue light hole transport layer, green light emissive layer and red light emissive layer, a blue light emissive layer formed on the blue light common layer, an electron transport layer formed on the blue light emissive layer, an electron injection layer formed on the electron transport layer, and an cathode formed on the electron injection layer; the green light emissive layer and the red light emissive layer being both QLED emissive layer, and the blue light emissive layer being an OLED emissive layer.

The substrate is a thin film transistor (TFT) substrate, comprising a base substrate, and a TFT array disposed on the base substrate.

The blue light emissive layer is made of a material comprising blue organic small molecular light-emitting material, and the blue light emissive layer is formed by a vapor deposition process.

The green light emissive layer and the red light emissive layer are made of a material comprising respectively green quantum dot light-emitting material and red quantum dot light-emitting material, and the green light emissive layer and the red light emissive layer are formed by a wet deposition process.

The blue light emissive layer has a thickness of 5-50 nm; and the green light emissive layer and the red light emissive layer have a thickness of 1 nm-100 nm.

The present invention also provides a manufacturing method of display device, which comprises the steps of: Step 1: providing a substrate, defining a plurality of blue sub-pixel areas, green sub-pixel areas and red sub-pixel areas arranged as an array on the substrate; Step 2: forming in the blue sub-pixel areas, from the bottom up: a first anode, a blue light hole injection layer, and a blue light hole transport layer; forming in the green sub-pixel areas, from the bottom up: a second anode, a green light hole injection layer, a green light hole transport layer, and a green light emissive layer; forming in the red sub-pixel areas, from the bottom up: a third anode, a red light hole injection layer, a red light hole transport layer, and a red light emissive layer; the blue light hole injection layer, the blue light hole transport layer, the green light hole injection layer, the green light hole transport layer, the green light emissive layer, the red light hole injection layer, the red light hole transport layer, and the red light emissive layer being all formed by a wet deposition process; both the green light emissive layer and the red light emissive layer being QLED emissive layer; Step 3: using a vapor deposition process to form on the blue light hole transport layer, the green light emissive layer and the red light emissive layer, from the bottom up: a blue light common layer, a blue light emissive layer, an electron transport layer, an electron injection layer, and an cathode, to obtain a blue OLED, a green QLED and a red QLED on the substrate; the blue light emissive layer being an OLED emissive layer; the blue OLED comprising: the first node, blue light hole injection layer and blue light hole transport layer; the green QLED comprising: the second anode, the green light hole injection layer, the green light hole transport layer, and the green light emissive layer; the red QLED comprising: the third anode, the red light hole injection layer, the red light hole transport layer, and the red light emissive layer; the blue OLED, the green QLED and the red QLED further commonly comprising: the blue light common layer, the blue light emissive layer, the electron transport layer, the electron injection layer formed on the electron transport layer, and the cathode; Step 4: disposing a sealant and a cover in series on the cathode to obtain a self-luminous display device.

The substrate is a thin film transistor (TFT) substrate, comprising a base substrate, and a TFT array disposed on the base substrate.

The blue light emissive layer is made of a material comprising blue organic small molecular light-emitting material.

The green light emissive layer and the red light emissive layer are made of a material comprising respectively green quantum dot light-emitting material and red quantum dot light-emitting material.

The blue light emissive layer has a thickness of 5-50 nm; and the green light emissive layer and the red light emissive layer have a thickness of 1 nm-100 nm.

The present invention provides a self-luminous display device, which comprises a substrate, a blue OLED, a green QLED and a red QLED, all disposed on the substrate, a sealant disposed on the blue OLED, green QLED and red QLED, and a cover plate disposed on the sealant to cover the substrate; the substrate being disposed with a plurality of blue sub-pixel areas, green sub-pixel areas and red sub-pixel areas arranged as an array; the blue OLED comprising: a first anode formed on the blue sub-pixel area, a blue light hole injection layer disposed on the first anode, and a blue light hole transport layer disposed on the blue light hole injection layer; the green QLED comprising: a second anode formed on the green sub-pixel area, a green light hole injection layer disposed on the second anode, a green light hole transport layer disposed on the green light hole injection layer, and a green light emissive layer disposed on the green light hole transport layer; the red QLED comprising: a third anode formed on the red sub-pixel area, a red light hole injection layer disposed on the third anode, a red light hole transport layer disposed on the red light hole injection layer, and a red light emissive layer disposed on the red light hole transport layer; the blue OLED, green QLED and red QLED further commonly comprising: a blue light common layer formed on the blue light hole transport layer, green light emissive layer and red light emissive layer, a blue light emissive layer formed on the blue light common layer, an electron transport layer formed on the blue light emissive layer, an electron injection layer formed on the electron transport layer, and an cathode formed on the electron injection layer; the green light emissive layer and the red light emissive layer being both QLED emissive layer, and the blue light emissive layer being an OLED emissive layer; wherein the substrate being a thin film transistor (TFT) substrate, comprising a base substrate, and a TFT array disposed on the base substrate; wherein the blue light emissive layer being made of a material comprising blue organic small molecular light-emitting material, and the blue light emissive layer being formed by a vapor deposition process.

Compared to the known techniques, the present invention provides the following advantages: the present invention provides a self-luminous display device, which comprises a blue OLED, a green QLED and a red QLED, and the blue OLED, green QLED and red QLED sharing a common blue light emissive layer formed on all the sub-pixel areas; the green light emissive layer and the red light emissive layer disposed at corresponding green and red sub-pixel areas respectively; the blue light emissive layer formed by a vapor deposition process to overcome the problems of low emission efficiency and short life-span when manufacturing blue OLED with wet deposition; while the red and green light emissive layers formed by a wet deposition process to overcome the problems of low material utilization and high cost when manufacturing red and green QLED with vapor deposition. The present invention can reduce manufacturing cost and improve competiveness without affecting the luminous efficiency and life-span. The present invention also provides a manufacturing method of a self-luminous display device, to reduce manufacturing cost and improve competiveness without affecting the luminous efficiency and life-span.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing a structure of a self-luminous display device provided by an embodiment of the present invention; and

FIG. 2 is a schematic view showing a flowchart of the manufacturing method of a self-luminous display device provided by an embodiment of the present invention.

### DETAILED DESCRIPTION OF THE PREFERRED EMBODIMENTS

To further explain the technical means and effect of the present invention, the following refers to embodiments and drawings for detailed description.

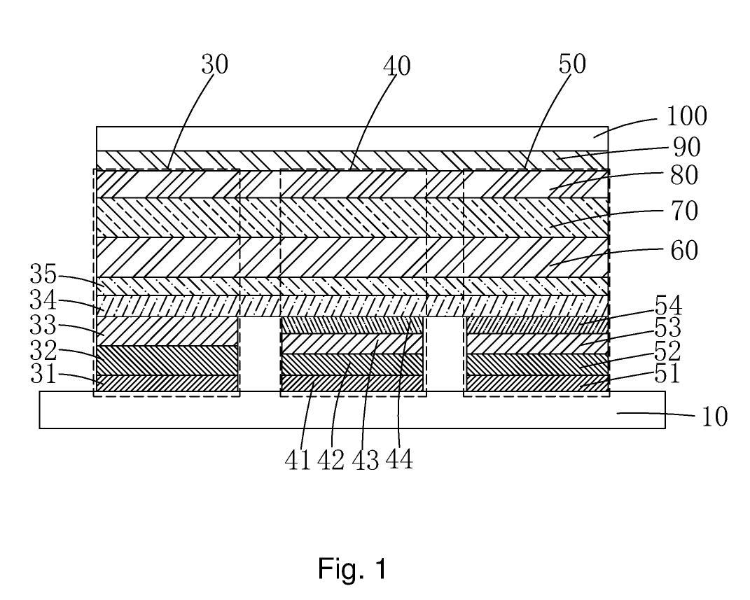

Refer to FIG. 1. The present invention provides a self-luminous display device, which comprises: a substrate 10, a blue OLED 30, a green QLED 40 and a red QLED 50, all disposed on the substrate 10, a sealant 90 disposed on the blue OLED 30, green QLED 40 and red QLED 50, and a cover plate 100 disposed on the sealant 90 to cover the substrate 10.

The substrate 10 is disposed with a plurality of blue sub-pixel areas, green sub-pixel areas and red sub-pixel areas arranged as an array.

The blue OLED 30 comprises: a first anode 31 formed on the blue sub-pixel area, a blue light hole injection layer 32 disposed on the first anode 31, and a blue light hole transport layer 33 disposed on the blue light hole injection layer 32.

The green QLED 40 comprises: a second anode 41 formed on the green sub-pixel area, a green light hole injection layer 42 disposed on the second anode 41, a green light hole transport layer 43 disposed on the green light hole injection layer 42, and a green light emissive layer 44 disposed on the green light hole transport layer 43.

The red QLED 50 comprises: a third anode 51 formed on the red sub-pixel area, a red light hole injection layer 52 disposed on the third anode 51, a red light hole transport layer 53 disposed on the red light hole injection layer 52, and a red light emissive layer 54 disposed on the red light hole transport layer 53.

The blue OLED 30, green QLED 40 and red QLED 50 further commonly comprising: a blue light common layer 34 formed on the blue light hole transport layer 33, green light emissive layer 44 and red light emissive layer 54, a blue light emissive layer 35 formed on the blue light common layer 34, an electron transport layer 60 formed on the blue light emissive layer 35, an electron injection layer 70 formed on the electron transport layer 60, and an cathode 80 formed on the electron injection layer 70.

The green light emissive layer 44 and the red light emissive layer 54 are both QLED emissive layer, and are formed by a wet deposition process. Specifically, the wet deposition process is ink-jet printing (IJP) or nozzle printing, and can form a coating layer directly according to a preset pattern.

The blue light emissive layer 35 is an OLED emissive layer, and is formed by a vapor deposition process. Specifically, the substrate 10 is a thin film transistor (TFT) substrate, comprising a base substrate, and a TFT array disposed on the base substrate. The TFT comprises a semiconductor layer, an insulating layer, a source/drain, and a gate, all stacked accordingly.

The first anode 31, second anode 41 and third anode 51 are used for injecting holes into the blue light hole injection layer 32, green light hole injection layer 42, and red light hole injection layer 52 respectively, and are all made of transparent conductive metal material, such as, indium tin oxide (ITO), indium zinc oxide (IZO), zinc oxide (ZnO), and so on, high work function metals, such as, gold (Au), platinum (Pt), silver (Ag) and copper (Cu), and so on, or an alloy of the above metals. The above anode materials may be used alone, or two or more may be used in combination. The thickness is 20-200 nm. Preferably, the anodes are made of ITO, and preferably with a thickness of 100 nm.

The blue light hole injection layer 32, green light hole injection layer 42, and red light hole injection layer 52 are used to assist the holes from the first anode 31, second anode 41 and third anode 51 injected into the blue light hole transport layer 33, green light hole transport layer 43 and red light hole transport layer 53 respectively, and are all made of an organic small molecule hole injection material or a polymer small molecule hole injection material. The thickness is 1-100 nm. Preferably, the material is PEDT:PSS, and preferably with a thickness of 10 nm.

The molecular structure of PEDT:PSS is:

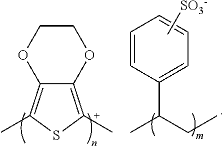

The blue light hole transport layer 33 is for transporting the holes from the blue light hole injection layer 32 to the blue light common layer 34, and the green light hole transport layer 43 and the red light hole transport layer 53 are for transporting the holes from the green light hole injection layer 42 and red light hole injection layer 52 to the green light emissive layer 44 and red light emissive layer 54. The blue light hole transport layer 33, green light hole transport layer 43, and red light hole transport layer 53 are all made of an organic small molecule hole transport material or a polymer small molecule hole transport material. The thickness is 1-100 nm. Preferably, the material is Poly-TPD, and preferably with a thickness of 20 nm.

The molecular structure of Poly-TPD is:

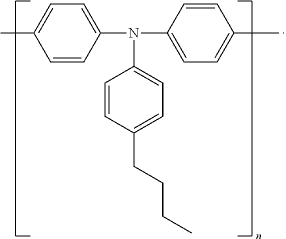

The green light emissive layer 44 and red light emissive layer 54 are used for the composite hole and electron emission, and are made of materials comprising respectively green quantum dot light-emitting material and red quantum dot light-emitting material. The thickness is 1-100 nm. The preferred material is CdSe—ZnS core-shell quantum dots (QDs) with a cadmium selenide core and a zinc sulfide shell of the core-shell structure, preferably a thickness of both 30 nm.

The blue light common layer 34 is for transporting holes from the blue light transport layer 33 to the blue light emissive layer 35 and transporting electrons from to the green light emissive layer 44 and red light emissive layer 54, and is made of an organic small molecule hole transport material. The thickness is 2-20 nm. The preferred material is NPB, and preferably with a thickness of 10 nm.

The molecular structure of NPB is:

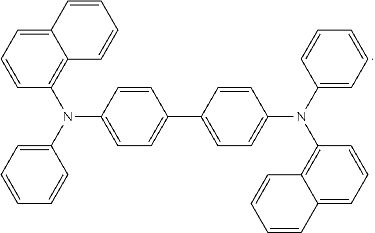 [SMILES: c1ccc(N(c2ccc(-c3ccc(N(c4ccccc4)c4cccc5ccccc45)cc3)cc2)c2cccc3ccccc23)cc1]

The blue light emissive layer 35 is for composite electron and hole emission in the blue light emissive layer 35 and transporting the electrons from the electron transport layer 60 to the blue light common layer 34, and is made of a material comprising blue organic small molecular light-emitting material. The thickness is 5-50 nm. The preferred material is DPVBi, and preferably with a thickness of 25 nm.

The molecular structure of DPVBi is:

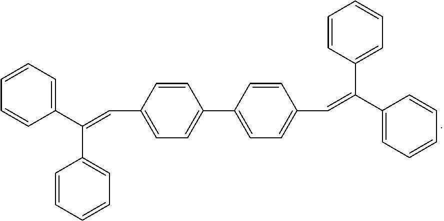 [SMILES: C(=C(c1ccccc1)c1ccccc1)c1ccc(-c2ccc(C=C(c3ccccc3)c3ccccc3)cc2)cc1]

The electron transport layer 60 is for transporting the electrons from the electron injection layer 70 to the blue light emissive layer 35, and is made of an organic small molecule electron transport material. The thickness is 5-50 nm. The preferred material is TPBi, and preferably with a thickness of 2 nm.

The molecular structure of TPBi is:

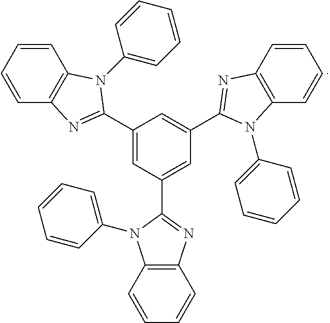 [SMILES: c1ccc(-n2c(-c3cc(-c4nc5ccccc5n4-c4ccccc4)cc(-c4nc5ccccc5n4-c4ccccc4)c3)nc3ccccc32)cc1]

The electron injection layer 70 is for the cathode 8 to inject the electrons to the electron transport layer 60, and is made of a material metal complexes, such as, 8-Hydroxyquinolinolato-lithium (Liq), or an alkali metal and salts, such as, lithium (Li), sodium (Na), potassium (K), rubidium (Rb), cesium (Cs), lithium fluoride (LiF), lithium carbonate (Li2CO3), lithium chloride (LiCl), sodium fluoride (NaF), sodium carbonate (Na2CO3), sodium chloride (NaCl), cesium fluoride (of CsF), cesium carbonate (Cs2CO3), and cesium chloride (CsCl), or alkaline earth metal and salts, such as, magnesium (Mg), calcium (Ca), strontium (Sr), barium (Ba), calcium fluoride (CaF2), calcium carbonate (CaCO3), strontium fluoride (SrF2), strontium carbonate (SrCO3), fluorinated barium (BaF2), and barium carbonate (BaCO3). The thickness is 0.5-10 nm. The preferred materials is LiF, and preferably with a thickness of 1 nm.

The cathode 80 injects electrons into the electron injection layer 70, and is made of a low work function metal material, such as, lithium (Li), magnesium (Mg), calcium (Ca), strontium (Sr), lanthanum (La), cerium (Ce), europium (Eu), ytterbium (Yb), aluminum (Al), cesium (the Cs), rubidium (Rb), etc.), or an alloy of low work function metals. The above materials may be used alone, or two types or more in combination. The thickness is of 50-1000 nm. The preferred material is Al, and preferably with a thickness of 100 nm.

The sealant 90 and cover plate 100 are to block the erosion from water and oxygen on OLED and QLED.

It should be noted that in the above self-luminous display device, the blue OLED 30, green QLED 40 and red QLED 50 shares a blue light emissive layer 35 formed on all the sub-pixel areas, which can be made by a vapor deposition process to overcome the problems of low emission efficiency and short life-span when manufacturing blue OLED with wet deposition. The green light emissive layer 44 and the red light emissive layer 54 are disposed at corresponding green and red sub-pixel areas respectively; and the red and green light emissive layers 54, 44 may be formed by a wet deposition process to overcome the problems of low material utilization and high cost when manufacturing red and green QLED with vapor deposition. The present invention can reduce manufacturing cost and improve competiveness without affecting the luminous efficiency and life-span.

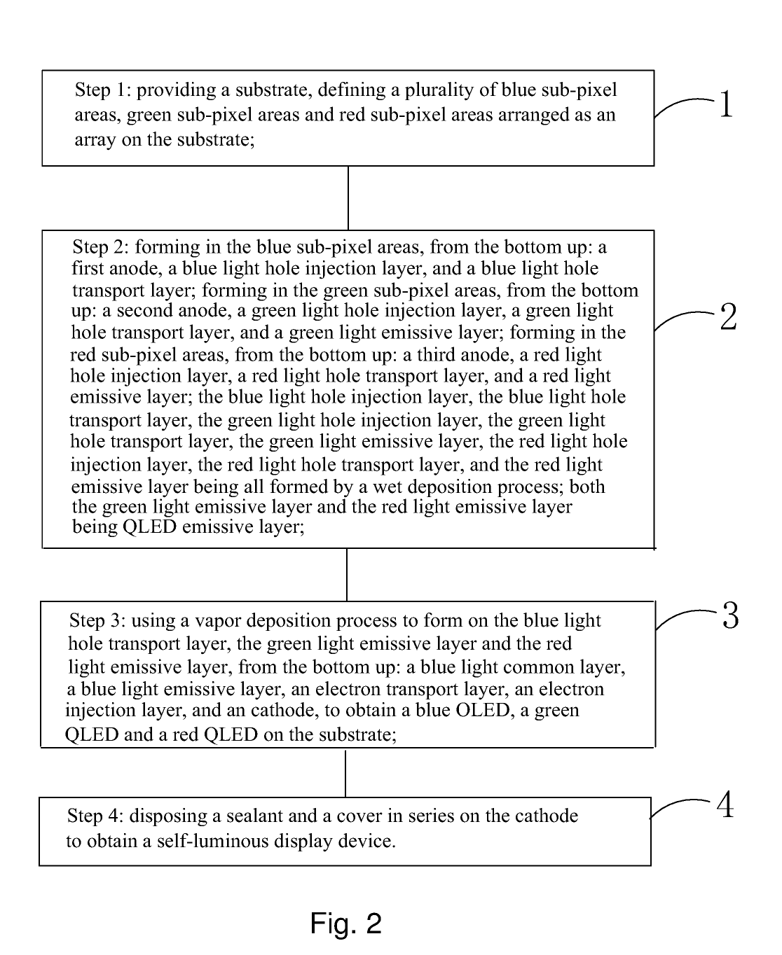

Refer to FIG. 2, the present invention also provides a manufacturing method of a self-luminous display device, which comprises the following steps of:

Step 1: providing a substrate 10, defining a plurality of blue sub-pixel areas, green sub-pixel areas and red sub-pixel areas arranged as an array on the substrate 10.

Specifically, the substrate 10 is a thin film transistor (TFT) substrate, comprising a base substrate, and a TFT array disposed on the base substrate. The TFT comprises a semiconductor layer, an insulating layer, a source/drain, and a gate, all stacked accordingly.

Step 2: forming in the blue sub-pixel areas, from the bottom up: a first anode 31, a blue light hole injection layer 32, and a blue light hole transport layer 33; forming in the green sub-pixel areas, from the bottom up: a second anode 41, a green light hole injection layer 42, a green light hole transport layer 43, and a green light emissive layer 44; forming in the red sub-pixel areas, from the bottom up: a third anode 51, a red light hole injection layer 52, a red light hole transport layer 53, and a red light emissive layer 54.

Specifically, the first anode 31, second anode 41 and third anode 51 are used for injecting holes into the blue light hole injection layer 32, green light hole injection layer 42, and red light hole injection layer 52 respectively, and are all made of transparent conductive metal material, such as, indium tin oxide (ITO), indium zinc oxide (IZO), zinc oxide (ZnO), and so on, high work function metals, such as, gold (Au), platinum (Pt), silver (Ag) and copper (Cu), and so on, or an alloy of the above metals. The above anode materials may be used alone, or two or more may be used in combination. The thickness is 20-200 nm. Preferably, the anodes are made of ITO, and preferably with a thickness of 100 nm.

The blue light hole injection layer 32, green light hole injection layer 42, and red light hole injection layer 52 are used to assist the holes from the first anode 31, second anode 41 and third anode 51 injected into the blue light hole transport layer 33, green light hole transport layer 43 and red light hole transport layer 53 respectively, and are all made of an organic small molecule hole injection material or a polymer small molecule hole injection material. The thickness is 1-100 nm. Preferably, the material is PEDT:PSS, and preferably with a thickness of 10 nm.

The molecular structure of PEDT:PSS is:

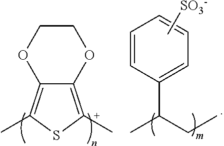

The blue light hole transport layer 33 is for transporting the holes from the blue light hole injection layer 32 to the blue light common layer 34, and the green light hole transport layer 43 and the red light hole transport layer 53 are for transporting the holes from the green light hole injection layer 42 and red light hole injection layer 52 to the green light emissive layer 44 and red light emissive layer 54. The blue light hole transport layer 33, green light hole transport layer 43, and red light hole transport layer 53 are all made of an organic small molecule hole transport material or a polymer small molecule hole transport material. The thickness is 1-100 nm. Preferably, the material is Poly-TPD, and preferably with a thickness of 20 nm.

The molecular structure of Poly-TPD is:

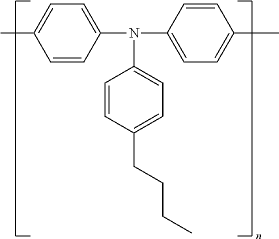

The blue light hole injection layer 32, the blue light hole transport layer 33, the green light hole injection layer 42, the green light hole transport layer 43, the green light emissive layer 44, the red light hole injection layer 52, the red light hole transport layer 53, and the red light emissive layer 54 are all formed by a wet deposition process, which has the advantages of high material utilization and low cost compared to vapor deposition process.

Specifically, the wet deposition process is ink-jet printing (IJP) or nozzle printing, and can form a coating layer directly according to a preset pattern.

Specifically, both the green light emissive layer 44 and red light emissive layer 54 are QLED emissive layers. The green light emissive layer 44 and red light emissive layer 54 are used for the composite hole and electron emission, and are made of materials comprising respectively green quantum dot light-emitting material and red quantum dot light-emitting material. The thickness is 1-100 nm. The preferred material is CdSe—ZnS core-shell quantum dots (QDs) with a cadmium selenide core and a zinc sulfide shell of the core-shell structure, preferably a thickness of both 30 nm.

Step 3: using a vapor deposition process to form on the blue light hole transport layer 33, the green light emissive layer 44 and the red light emissive layer 54, from the bottom up: a blue light common layer 34, a blue light emissive layer 35, an electron transport layer 60, an electron injection layer 70, and an cathode 80.

Specifically, the blue light common layer 34 is for transporting holes from the blue light transport layer 33 to the blue light emissive layer 35 and transporting electrons from to the green light emissive layer 44 and red light emissive layer 54, and is made of an organic small molecule hole transport material. The thickness is 2-20 nm. The preferred material is NPB, and preferably with a thickness of 10 nm.

The molecular structure of NPB is:

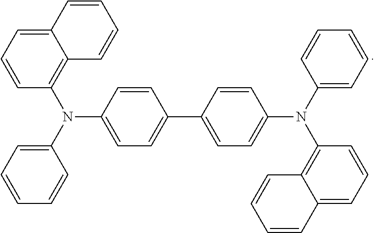 [SMILES: c1ccc(N(c2ccc(-c3ccc(N(c4ccccc4)c4cccc5ccccc45)cc3)cc2)c2cccc3ccccc23)cc1]

The electron transport layer 60 is for transporting the electrons from the electron injection layer 70 to the blue light emissive layer 35, and is made of an organic small molecule electron transport material. The thickness is 5-50 nm. The preferred material is TPBi, and preferably with a thickness of 2 nm.

The molecular structure of TPBi is:

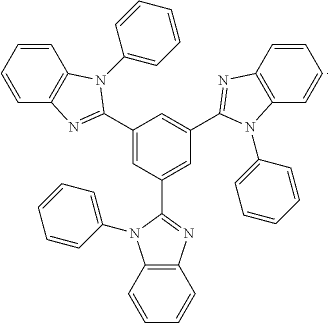 [SMILES: c1ccc(-n2c(-c3cc(-c4nc5ccccc5n4-c4ccccc4)cc(-c4nc5ccccc5n4-c4ccccc4)c3)nc3ccccc32)cc1]

The electron injection layer 70 is for the cathode 8 to inject the electrons to the electron transport layer 60, and is made of a material metal complexes, such as, 8-Hydroxyquinolinolato-lithium (Liq), or an alkali metal and salts, such as, lithium (Li), sodium (Na), potassium (K), rubidium (Rb), cesium (Cs), lithium fluoride (LiF), lithium carbonate (Li2CO3), lithium chloride (LiCl), sodium fluoride (NaF), sodium carbonate (Na2CO3), sodium chloride (NaCl), cesium fluoride (of CsF), cesium carbonate (Cs2CO3), and cesium chloride (CsCl), or alkaline earth metal and salts, such as, magnesium (Mg), calcium (Ca), strontium (Sr), barium (Ba), calcium fluoride (CaF2), calcium carbonate (CaCO3), strontium fluoride (SrF2), strontium carbonate (SrCO3), fluorinated barium (BaF2), and barium carbonate (BaCO3). The thickness is 0.5-10 nm. The preferred materials is LiF, and preferably with a thickness of 1 nm.

The cathode 80 injects electrons into the electron injection layer 70, and is made of a low work function metal material, such as, lithium (Li), magnesium (Mg), calcium (Ca), strontium (Sr), lanthanum (La), cerium (Ce), europium (Eu), ytterbium (Yb), aluminum (Al), cesium (the Cs), rubidium (Rb), etc.), or an alloy of low work function metals. The above materials may be used alone, or two types or more in combination. The thickness is of 50-1000 nm. The preferred material is Al, and preferably with a thickness of 100 nm.

The blue light common layer 34, the blue light emissive layer 35, the electron transport layer 60, the electron injection layer 70, and the cathode 80 are all formed by a vapor deposition process, which has the advantages of low luminous efficiency and short life-span compared to vapor deposition process to manufacture a blue OLED.

The blue light emissive layer 35 is an OLED emissive layer, and is for composite electron and hole emission in the blue light emissive layer 35 and transporting the electrons from the electron transport layer 60 to the blue light common layer 34, and is made of a material comprising blue organic small molecular light-emitting material. The thickness is 5-50 nm. The preferred material is DPVBi, and preferably with a thickness of 25 nm.

The molecular structure of DPVBi is:

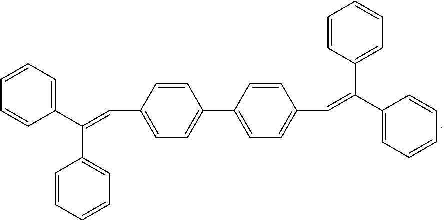 [SMILES: C(=C(c1ccccc1)c1ccccc1)c1ccc(-c2ccc(C=C(c3ccccc3)c3ccccc3)cc2)cc1]

Step 4: disposing a sealant 90 and a cover 100 in series on the cathode 90 to obtain a self-luminous display device.

Specifically, the sealant 80 and cover plate 90 are to block the erosion from water and oxygen on OLED and QLED.

In summary, the present invention provides a self-luminous display device, which comprises a blue OLED, a green QLED and a red QLED, and the blue OLED, green QLED and red QLED sharing a common blue light emissive layer formed on all the sub-pixel areas; the green light emissive layer and the red light emissive layer disposed at corresponding green and red sub-pixel areas respectively; the blue light emissive layer formed by a vapor deposition process to overcome the problems of low emission efficiency and short life-span when manufacturing blue OLED with wet deposition; while the red and green light emissive layers formed by a wet deposition process to overcome the problems of low material utilization and high cost when manufacturing red and green QLED with vapor deposition. The present invention can reduce manufacturing cost and improve competiveness without affecting the luminous efficiency and life-span. The present invention also provides a manufacturing method of a self-luminous display device, to reduce manufacturing cost and improve competiveness without affecting the luminous efficiency and life-span.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A self-luminous display device, which comprises: a substrate, a blue OLED, a green QLED and a red QLED, all disposed on the substrate, a sealant disposed on the blue OLED, green QLED and red QLED, and a cover plate disposed on the sealant to cover the substrate;
the substrate being disposed with a plurality of blue sub-pixel areas, green sub-pixel areas and red sub-pixel areas arranged as an array;
the blue OLED comprising: a first anode formed on the blue sub-pixel area, a blue light hole injection layer disposed on the first anode, and a blue light hole transport layer disposed on the blue light hole injection layer;
the green QLED comprising: a second anode formed on the green sub-pixel area, a green light hole injection layer disposed on the second anode, a green light hole transport layer disposed on the green light hole injection layer, and a green light emissive layer disposed on the green light hole transport layer;
the red QLED comprising: a third anode formed on the red sub-pixel area, a red light hole injection layer disposed on the third anode, a red light hole transport layer disposed on the red light hole injection layer, and a red light emissive layer disposed on the red light hole transport layer;
the blue OLED, green QLED and red QLED further commonly comprising: a blue light common layer formed on the blue light hole transport layer, green light emissive layer and red light emissive layer, a blue light emissive layer formed on the blue light common layer, an electron transport layer formed on the blue light emissive layer, an electron injection layer formed on the electron transport layer, and an cathode formed on the electron injection layer;
the green light emissive layer and the red light emissive layer being both QLED emissive layer, and the blue light emissive layer being an OLED emissive layer.

2. The self-luminous display device as claimed in claim 1, wherein the substrate is a thin film transistor (TFT) substrate, comprising a base substrate, and a TFT array disposed on the base substrate.

3. The self-luminous display device as claimed in claim 1, wherein the blue light emissive layer is made of a material comprising blue organic small molecular light-emitting material, and the blue light emissive layer is formed by a vapor deposition process.

4. The self-luminous display device as claimed in claim 1, wherein the green light emissive layer and the red light emissive layer are made of a material comprising respectively green quantum dot light-emitting material and red quantum dot light-emitting material, and the green light emissive layer and the red light emissive layer are formed by a wet deposition process.

5. The self-luminous display device as claimed in claim 1, wherein the blue light emissive layer has a thickness of 5-50 nm; and both the green light emissive layer and the red light emissive layer have a thickness of 1 nm-100 nm.

6. A manufacturing method of display device, which comprises the steps of:
Step 1: providing a substrate, defining a plurality of blue sub-pixel areas, green sub-pixel areas and red sub-pixel areas arranged as an array on the substrate;
Step 2: forming in the blue sub-pixel areas, from the bottom up: a first anode, a blue light hole injection layer, and a blue light hole transport layer;
forming in the green sub-pixel areas, from the bottom up: a second anode, a green light hole injection layer, a green light hole transport layer, and a green light emissive layer;
forming in the red sub-pixel areas, from the bottom up: a third anode, a red light hole injection layer, a red light hole transport layer, and a red light emissive layer;
the blue light hole injection layer, the blue light hole transport layer, the green light hole injection layer, the green light hole transport layer, the green light emissive layer, the red light hole injection layer, the red light hole transport layer, and the red light emissive layer being all formed by a wet deposition process;
both the green light emissive layer and the red light emissive layer being QLED emissive layer;
Step 3: using a vapor deposition process to form on the blue light hole transport layer, the green light emissive layer and the red light emissive layer, from the bottom up: a blue light common layer, a blue light emissive layer, an electron transport layer, an electron injection layer, and an cathode, to obtain a blue OLED, a green QLED and a red QLED on the substrate;
the blue light emissive layer being an OLED emissive layer;
the blue OLED comprising: the first node, blue light hole injection layer and blue light hole transport layer; the green QLED comprising: the second anode, the green light hole injection layer, the green light hole transport layer, and the green light emissive layer; the red QLED comprising: the third anode, the red light hole injection layer, the red light hole transport layer, and the red light emissive layer; the blue OLED, the green QLED and the red QLED further commonly comprising: the blue light common layer, the blue light emissive layer, the electron transport layer, the electron injection layer formed on the electron transport layer, and the cathode;
Step 4: disposing a sealant and a cover in series on the cathode to obtain a self-luminous display device.

7. The manufacturing method of display device as claimed in claim 6, wherein the substrate is a thin film transistor (TFT) substrate, comprising a base substrate, and a TFT array disposed on the base substrate.

8. The manufacturing method of display device as claimed in claim 6, wherein the blue light emissive layer is made of a material comprising blue organic small molecular light-emitting material.

9. The manufacturing method of display device as claimed in claim 6, wherein the green light emissive layer and the red light emissive layer are respectively made of a material comprising green quantum dot light-emitting material and red quantum dot light-emitting material.

10. The manufacturing method of display device as claimed in claim 6, wherein the blue light emissive layer has a thickness of 5-50 nm; and both the green light emissive layer and the red light emissive layer have a thickness of 1 nm-100 nm.

11. A self-luminous display device, which comprises: a substrate, a blue OLED, a green QLED and a red QLED, all disposed on the substrate, a sealant disposed on the blue OLED, green QLED and red QLED, and a cover plate disposed on the sealant to cover the substrate;
the substrate being disposed with a plurality of blue sub-pixel areas, green sub-pixel areas and red sub-pixel areas arranged as an array;
the blue OLED comprising: a first anode formed on the blue sub-pixel area, a blue light hole injection layer disposed on the first anode, and a blue light hole transport layer disposed on the blue light hole injection layer;
the green QLED comprising: a second anode formed on the green sub-pixel area, a green light hole injection layer disposed on the second anode, a green light hole transport layer disposed on the green light hole injection layer, and a green light emissive layer disposed on the green light hole transport layer;
the red QLED comprising: a third anode formed on the red sub-pixel area, a red light hole injection layer disposed on the third anode, a red light hole transport layer disposed on the red light hole injection layer, and a red light emissive layer disposed on the red light hole transport layer;
the blue OLED, green QLED and red QLED further commonly comprising: a blue light common layer formed on the blue light hole transport layer, green light emissive layer and red light emissive layer, a blue light emissive layer formed on the blue light common layer, an electron transport layer formed on the blue light emissive layer, an electron injection layer formed on the electron transport layer, and an cathode formed on the electron injection layer;
the green light emissive layer and the red light emissive layer being both QLED emissive layer, and the blue light emissive layer being an OLED emissive layer;
wherein the substrate is a thin film transistor (TFT) substrate, comprising a base substrate, and a TFT array disposed on the base substrate;
wherein the blue light emissive layer is made of a material comprising blue organic small molecular light-emitting material, and the blue light emissive layer is formed by a vapor deposition process.

12. The self-luminous display device as claimed in claim 11, wherein the green light emissive layer and the red light emissive layer are made of a material comprising respectively green quantum dot light-emitting material and red quantum dot light-emitting material, and the green light emissive layer and the red light emissive layer are formed by a wet deposition process.

13. The self-luminous display device as claimed in claim 11, wherein the blue light emissive layer has a thickness of 5-50 nm; and both the green light emissive layer and the red light emissive layer have a thickness of 1 nm-100 nm.
